(19) United States
(12) Patent Application Publication
(10) Pub. No.: US 2025/0180606 A1
(43) Pub. Date: Jun. 5, 2025

(54) VOLTAGE DIVIDER CIRCUIT AND SEMICONDUCTOR DEVICE USING THE SAME

(71) Applicant: ABLIC Inc., Nagano (JP)

(72) Inventor: Shinjiro KATO, Nagano (JP)

(73) Assignee: ABLIC Inc., Nagano (JP)

(21) Appl. No.: 18/953,034

(22) Filed: Nov. 19, 2024

(30) Foreign Application Priority Data
Nov. 30, 2023 (JP) 2023-202584
May 21, 2024 (JP) 2024-082278

(51) Int. Cl. G01R 15/04; G01R 1/20; G01R 31/364

(52) U.S. Cl. CPC G01R 15/04; G01R 1/203; G01R 31/364

(57) ABSTRACT

A voltage divider circuit includes: a first terminal; a second terminal; a voltage divider output terminal; a first resistance group in which multiple resistance elements are connected between the first terminal and the voltage divider output terminal; a second resistance group in which multiple resistance elements are connected between the second terminal and the voltage divider output terminal; a first metal film connected to the first terminal and covering a region including at least a part of the first resistance group in plan view; and a second metal film connected to the second terminal and covering a region including at least a part of the second resistance group in plan view, and the second metal film further covers a part of the first resistance group.

### CROSS-REFERENCE TO RELATED APPLICATION

This application claims the priority benefits of Japanese application no. 2023-202584, filed on Nov. 30, 2023, and Japanese application no. 2024-082278, filed on May 21, 2024. The entirety of each of the above-mentioned patent applications is hereby incorporated by reference herein and made a part of this specification.

### BACKGROUND

### Technical Field

The present invention relates to a voltage divider circuit and a semiconductor device using the same.

### Description of Related Art

A secondary battery used in a portable device and the like may deteriorate due to overcharging or over-discharging. Thus, a semiconductor device for monitoring the battery voltage and protecting the battery is often connected between the positive terminal and the negative terminal. In such a semiconductor device, detection accuracy of about 10 mV or less is needed, and variations in detection accuracy for each of individual semiconductor devices is unable to be ignored in some cases.

As a technique for detecting a predetermined voltage, there is a method of comparing a reference voltage or a voltage to be measured by dividing the reference voltage or the voltage to be measured using a voltage divider circuit, and various voltage divider circuits have been proposed to enhance the detection accuracy.

In a semiconductor device, a voltage divider circuit may be used that includes multiple resistance elements formed of polycrystalline silicon connected in series. It is known that the resistance value of the polycrystalline silicon resistance element changes according to the hydrogen content.

In the manufacturing process of a semiconductor device, it is common to use processes containing hydrogen, such as the formation process of a silicon nitride film used for passivation and the alloy process, etc. As a result, during the manufacturing process of polycrystalline silicon resistance elements, hydrogen may infiltrate the polycrystalline silicon resistance elements, potentially causing variations in the resistance values of the respective resistance elements.

To suppress the hydrogen infiltration, for example, the invention described in Patent Literature 1 (Japanese Patent Application Laid-Open No. 2008-211115) suppresses hydrogen infiltration into the resistance elements by forming a metal film that covers the entirety of multiple resistance elements.

An aspect of the present invention provides a voltage divider circuit that achieves both the reduction of changes in the voltage divider output voltage due to temporal changes in the resistance value occurring in the resistance element and the suppression of area increase in the voltage divider circuit region.

### SUMMARY

A voltage divider circuit in an embodiment of the present invention includes:
a first terminal;
a second terminal;
a voltage divider output terminal;
a first resistance group in which multiple resistance elements are connected between the first terminal and the voltage divider output terminal;
a second resistance group in which multiple resistance elements are connected between the second terminal and the voltage divider output terminal;
a first metal film which is connected to the first terminal and covers a region that includes at least a part of the first resistance group in plan view; and
a second metal film which is connected to the second terminal and covers a region that includes at least a part of the second resistance group in plan view, and
the second metal film further covers a part of the first resistance group.

According to an aspect of the present invention, a voltage divider circuit can be provided that achieves both the reduction of changes in the voltage divider output voltage due to temporal changes in the resistance value occurring in the resistance element and the suppression of area increase in the voltage divider circuit region.

### BRIEF DESCRIPTION OF THE DRAWINGS

FIG. 1 is a circuit diagram of a voltage divider circuit in an embodiment of the present invention.

FIG. 2 is a schematic top view (perspective view) of the voltage divider circuit illustrated in FIG. 1.

FIG. 3 is a schematic cross-sectional view along the line III-III illustrated in FIG. 2.

FIG. 4 is a schematic cross-sectional view along the line IV-IV illustrated in FIG. 2.

FIG. 5 is a graph illustrating the relationship between the rate of change in sheet resistance of polycrystalline silicon resistance elements and the voltage application time.

### DESCRIPTION OF THE EMBODIMENTS

A voltage divider circuit in an embodiment of the present invention is based on the following insights. The resistance element described in Patent Literature 1 can suppress the infiltration of hydrogen to some extent. However, the resistance value may change over time due to the potential difference between the resistance element and the metal film of the upper layer.

On the other hand, the metal film disposed on the upper layer of the resistance elements can be divided for each of the resistance elements, and each of the divided metal films can be connected to each of the resistance elements covered thereby to reduce the potential difference between the metal film and the resistance elements. However, in the configuration, it is needed to ensure a distance between adjacent metal films, and as the number of divisions of the metal film increases, the area of the unformed region of the metal film also increases. Consequently, the area of the voltage divider circuit region in which the resistance elements and metal films are formed also increases.

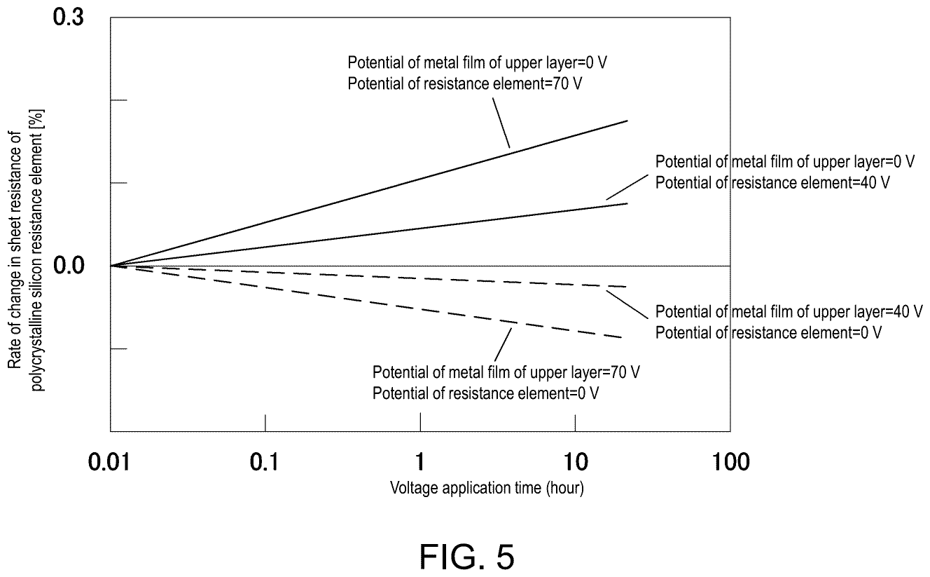

FIG. 5 is a graph illustrating the relationship between the rate of change in sheet resistance of polycrystalline silicon resistance elements and the voltage application time.

The graph illustrated by the solid line in FIG. 5 represents the characteristics in the case of the potential of the polycrystalline silicon resistance element being higher than the potential of the metal film of the upper layer, and the sheet resistance of the polycrystalline silicon resistance element changes over time in the direction of becoming higher. The graph illustrated by the dashed line in FIG. 5 represents the characteristics in the case of the potential of the polycrystalline silicon resistance element being lower than the potential of the metal film of the upper layer, and the sheet resistance of the polycrystalline silicon resistance element changes over time in the direction of becoming lower. In both cases, the larger the potential difference between the metal film of the upper layer and the polycrystalline silicon resistance element, the greater the change in sheet resistance of the polycrystalline silicon resistance element over time. The inventor found that such changes become significant in the case of the potential difference between the metal film and the resistance element being at or exceeding 40V. It is thought that the cause is the polarization of unstable molecules between the resistance element and the insulating film due to the long-term application of potential.

Thus, in a voltage divider circuit of an embodiment of the present invention, a first metal film covering a part of a first resistance group is connected to a first terminal, and a second metal film covering a part of the first resistance group and a second resistance group is connected to a second terminal.

As a result, the voltage divider circuit can provide a voltage divider circuit that achieves both the reduction of changes in the voltage divider output voltage due to temporal changes in the resistance value occurring in the resistance element and the suppression of area increase in the voltage divider circuit region.

The following describes in detail embodiments for implementing the present invention with reference to the drawings.

In the drawings, the same reference numerals are assigned to the same component parts, and duplicate descriptions may be omitted.

In addition, an X axis, a Y axis, and a Z axis illustrated in the drawings are considered to be mutually perpendicular. A Z axis direction may be referred to as a “height direction” or “thickness direction”. A face on a +Z direction side of each of members may be referred to as a “surface” or “top surface”, and a face on a −Z direction side may be referred to as a “back surface” or “bottom surface”. “Plan view” refers to viewing each of the members from the +Z direction side towards the −Z direction side.

Furthermore, the drawings are schematic, and the ratios of width, depth, and thickness are not as illustrated. The quantity, position, shape, structure, size, etc. of each of the members are not limited to the embodiments illustrated below, and can be adjusted to quantities, positions, shapes, structures, sizes, etc. that are preferable for implementing the present invention.

### Example of Embodiment

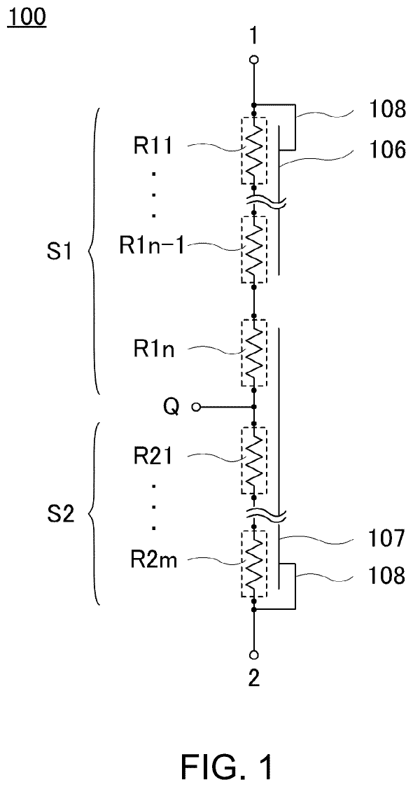

FIG. 1 is a circuit diagram of a voltage divider circuit in an embodiment of the present invention.

A voltage divider circuit 100 includes, as illustrated in FIG. 1, a first terminal 1, a second terminal 2, a voltage divider output terminal Q, a first resistance group S1, a second resistance group S2, a first metal film 106, and a second metal film 107.

The first resistance group S1 contains multiple resistance elements R1n (where n is a natural number) connected in series, with one end of the first resistance group S1 connected to the first terminal, and the other end connected to the second resistance group S2. The second resistance group S2 contains multiple resistance elements R2m (where m is a natural number) connected in series, with one end of the second resistance group S2 connected to the other end of the first resistance group S1, and the other end of the second resistance group S2 connected to the second terminal 2. The connection section between the first resistance group S1 and the second resistance group S2 is connected to the voltage divider output terminal Q.

In the voltage divider circuit 100, an output voltage Vout, which is the potential difference between the first terminal 1 and the second terminal 2 divided according to the ratio of the total resistance value of the first resistance group S1 to the total resistance value of the second resistance group S2, is output from the voltage divider output terminal Q. In the embodiment, the first terminal is connected to a VDD terminal of a semiconductor device that contains the voltage divider circuit 100. In the embodiment, the second terminal is connected to a GND terminal.

The first metal film 106 is formed on the upper layer of the resistance elements R11 to R1n−1 of the first resistance group S1. The first metal film 106 is electrically connected to the first terminal 1 by a metal wiring 108.

The second metal film 107 is formed on the upper layer of the resistance element R1n of

the first resistance group S1 and the resistance element R2m of the second resistance group S2. The second metal film 107 is electrically connected to the second terminal 2 by the metal wiring 108.

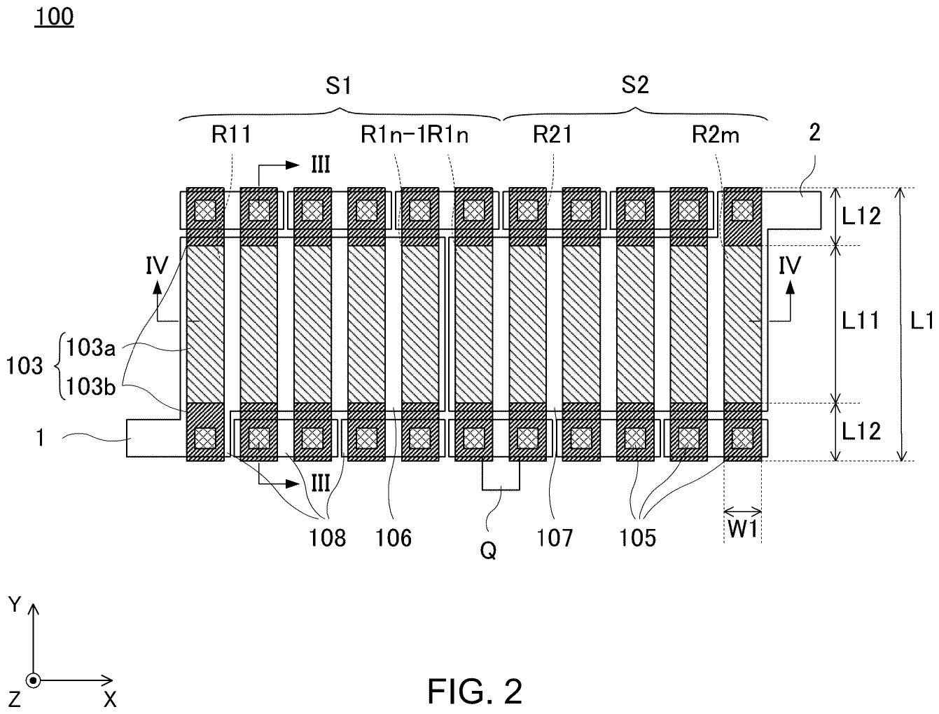

FIG. 2 is a schematic top view (perspective view) of the voltage divider circuit illustrated in FIG. 1.

Each of the resistance elements R1n and R2m is a polycrystalline silicon resistance element 103 formed by a polycrystalline silicon film. The polycrystalline silicon resistance element 103 is formed with a length L1 and a width W1. Each of the polycrystalline silicon resistance elements 103 contains a high resistance section 103a and a low resistance section 103b.The low resistance section 103b of the polycrystalline silicon resistance element 103 is connected to the metal wiring 108 through a contact hole 105, and is connected to the low resistance section 103b of the adjacent polycrystalline silicon resistance element 103. The low resistance section 103b is formed with a length L12 at both ends in the longitudinal direction of the polycrystalline silicon resistance element 103, and the high resistance section 103a is formed with a length L11 between the low resistance sections 103b. The high resistance section 103a has a P-type or N-type impurity concentration thereof adjusted to achieve the desired resistance value.

The first metal film 106 is formed on the upper layer of the resistance elements R11 to R1n−1 of the first resistance group S1, covering the entire high resistance sections 103a of the resistance elements R11 to R1n−1. The first metal film 106 is electrically connected to the first terminal 1 by the metal wiring 108. As a result, the resistance values of the resistance elements R11 to R1n−1 of the first resistance group S1 change over time in the direction of becoming lower.

The second metal film 107 is formed on the upper layer of the resistance element R1n of the first resistance group S1 and the resistance elements R21 to R2m of the second resistance group S2, covering the entire high resistance sections 103a. The second metal film 107 is electrically connected to the second terminal 2 by the metal wiring 108. As a result, the resistance values of the resistance elements R21 to R2m of the second resistance group S2 and the resistance element R1n of the first resistance group S1 change over time in the direction of becoming higher.

In this case, among the resistance elements covered by the second metal film 107, the potential difference between the resistance element R1n and the second metal film 107 becomes the largest, and the change in the resistance value of the resistance element R1n over time becomes the most significant. As a result, the resistance value of the entire first resistance group S1 changes over time in the direction of becoming higher. Thus, since the resistance values of both the entire first resistance group S1 and the entire second resistance group S2 change over time in the direction of becoming higher, the change in the ratio of resistance values can be minimized.

As a result, the change in the voltage divider output voltage due to the change in the resistance values of the resistance elements over time can be reduced. Additionally, by having two metal films, the first metal film and the second metal film, covering the upper layer of the polycrystalline silicon resistance elements, the gap between the metal films can be limited to one location, thereby suppressing the increase in the area of the voltage divider circuit region.

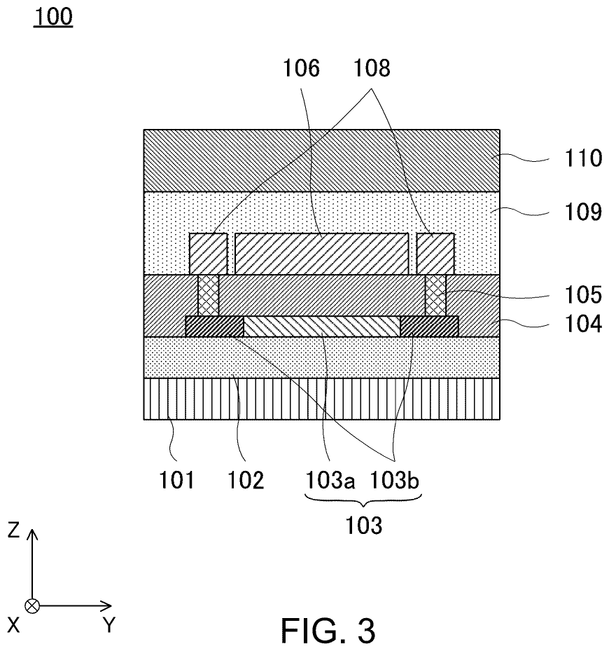

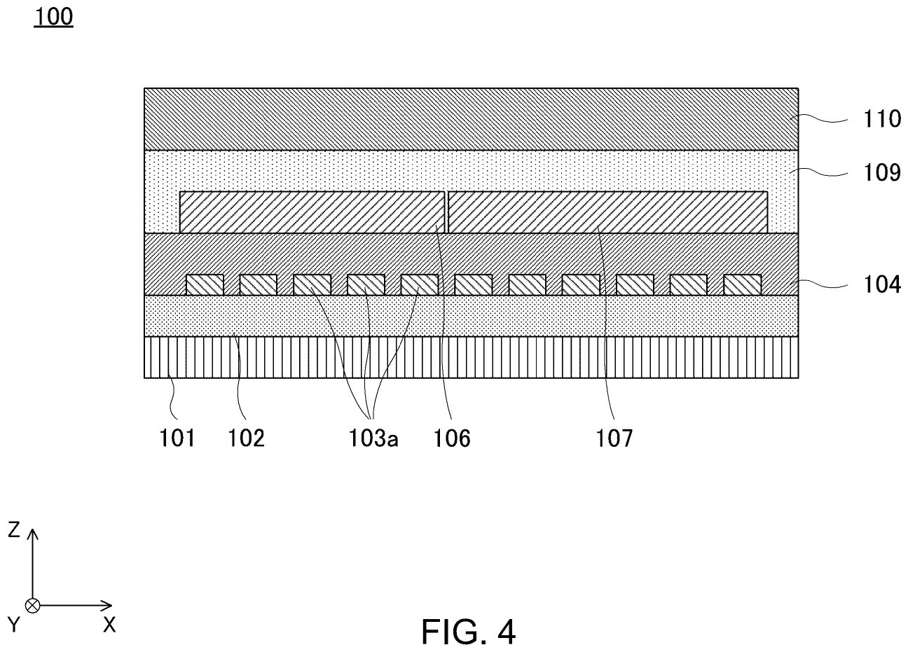

FIG. 3 is a schematic cross-sectional view along the line III-III illustrated in FIG. 2. FIG. 4 is a schematic cross-sectional view along the line IV-IV illustrated in FIG. 2.

As illustrated in FIGS. 3 and 4, the voltage divider circuit 100 is formed on the upper layer of a field insulating film 102 formed on the surface of a semiconductor substrate 101. Each of the resistance elements R1n and R2m is a polycrystalline silicon resistance element 103 formed by a polycrystalline silicon film.

An insulating film 104 is formed on the upper layer of the polycrystalline silicon resistance element 103, and the first metal film 106, the second metal film 107, and the metal wiring 108 are formed on the upper layer of the insulating film 104. The low resistance section 103b of the polycrystalline silicon resistance element 103 is connected to the metal wiring 108 through the contact hole 105. The first metal film 106, the second metal film 107, and the metal wiring 108 are formed, for example, by a multilayer film of Al—Si—Cu, a multilayer film of Al—Cu, etc.

A second insulating film 109 is formed on the upper layer of the first metal film 106 and the second metal film 107, and a silicon nitride film 110 is formed on the upper layer of the second insulating film 109.

Here, the first metal film 106 covering the upper layer of the high resistance sections 103a of the resistance elements R11 to R1n−1 of the first resistance group S1, the second metal film 107 covering the upper layer of the high resistance sections 103a of the resistance element R1n of the first resistance group S1 and the resistance element R2m of the second resistance group S2, and the metal wiring 108 are formed in the same layer. By forming the first metal film 106, the second metal film 107, and the metal wiring 108 in the same layer in this manner, it is possible to reduce variations in resistance values and temporal changes in resistance values occurring in the resistance elements without increasing the manufacturing process.

The present invention has been described with respect to an embodiment, but the present invention is not limited to the embodiment and includes designs, etc., within the scope that do not deviate from the essence of the present invention.

For example, in the embodiment, multiple resistance elements R1n (where n is a natural number) and R2m (where m is a natural number) of the voltage divider circuit are described as being connected in series, but all or a part of the resistance elements R1n and R2m may be connected in parallel. A circuit for adjusting resistance values, such as a fuse element or an MOS transistor, may be connected to the resistance elements. Additionally, while the region covered by the first metal film is described as the resistance elements R11 to R1n−1, and the region covered by the second metal film is described as the resistance elements R1n and R2m, this may be changed 10 to the position of any of the resistance elements in the region of the first resistance group S1.

What is claimed is:

1. A voltage divider circuit, comprising:
a first terminal;
a second terminal;
a voltage divider output terminal;
a first resistance group in which a plurality of resistance elements are connected between the first terminal and the voltage divider output terminal;
a second resistance group in which a plurality of resistance elements are connected between the second terminal and the voltage divider output terminal;
a first metal film, connected to the first terminal and covering a region that comprises at least a part of the first resistance group in plan view; and
a second metal film, connected to the second terminal and covering a region that comprises at least a part of the second resistance group in plan view, and
the second metal film further covering a part of the first resistance group.

2. The voltage divider circuit according to claim 1, wherein the first metal film and the second metal film are formed in the same layer.

3. A semiconductor device, comprising the voltage divider circuit according to claim 1.
